(19) United States
(12) Patent Application Publication
(10) Pub. No.: US 2012/0200296 A1
(43) Pub. Date: Aug. 9, 2012

(54) TECHNIQUE FOR IDENTIFYING AT LEAST ONE FAULTY LIGHT EMITTING DIODE IN MULTIPLE STRINGS OF LIGHT EMITTING DIODES

(75) Inventor: Jean-Jacques M. Avenel, Servon (FR)

(73) Assignees: NATIONAL SEMICONDUCTOR CORPORATION, Santa Clara, CA (US); Texas Instruments Incorporated, Dallas, TX (US)

(21) Appl. No.: 13/370,051

(22) Filed: Feb. 9, 2012

(30) Foreign Application Priority Data
Feb. 9, 2011 (EP) EP11305130.4

(51) Int. Cl. G01R 31/00

(52) U.S. Cl. 324/414

(57) ABSTRACT

A method includes receiving a first voltage from a first node associated with a first string of multiple light emitting diodes (LEDs). The method also includes receiving a second voltage from a second node associated with a second string of multiple LEDs. The method further includes identifying whether at least one of the LEDs has a fault using the first and second voltages. Identifying whether at least one of the LEDs has a fault could include comparing a difference between the first and second voltages to a threshold. Identifying whether at least one of the LEDs has a fault could also include determining whether a difference between the first and second voltages falls within a voltage range defined by higher and lower voltage limits.

### CROSS-REFERENCE TO RELATED APPLICATION AND PRIORITY CLAIM

This application claims priority under 35 U.S.C. §119 to European Patent Application No. EP 11305130 filed on Feb. 9, 2011, which is hereby incorporated by reference.

### TECHNICAL FIELD

This disclosure is generally directed to light emitting diodes (LEDs). More specifically, this disclosure is directed to a technique for identifying at least one faulty LED in multiple strings of LEDs.

### BACKGROUND

Many systems use light emitting diodes (LEDs) to generate illumination. For example, vehicles often use headlamps containing strings of LEDs. A string of LEDs typically includes multiple LEDs coupled in series, where a current through the string causes the LEDs to illuminate.

It is often difficult to determine whether a single LED or a small subset of LEDs in one or more strings has shorted out or otherwise suffered a fault. As a particular example, assume that a string includes ten LEDs coupled in series. The voltage across each LED could normally vary between 2.6V and 4.0V, so the voltage across the entire string could vary between 26V and 40V. In this case, it would be difficult to detect an approximate 3V variation caused by a short circuit of one LED in the string.

### BRIEF DESCRIPTION OF DRAWINGS

For a more complete understanding of this disclosure and its features, reference is now made to the following description, taken in conjunction with the accompanying drawings, in which:

FIG. 1 illustrates a first example system for identifying at least one faulty light emitting diode (LED) in multiple strings of LEDs according to this disclosure;

FIG. 2 illustrates a second example system for identifying at least one faulty LED in multiple strings of LEDs according to this disclosure; and

FIG. 3 illustrates an example method for identifying at least one faulty LED in multiple strings of LEDs according to this disclosure.

### DETAILED DESCRIPTION

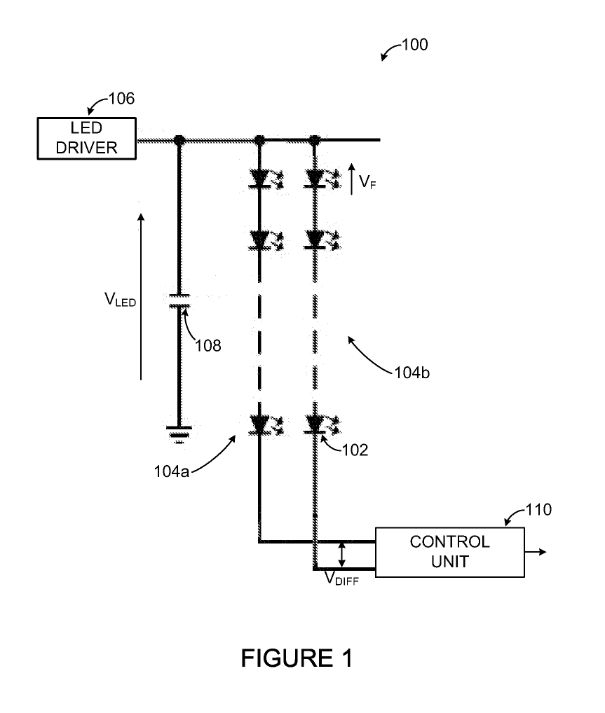

FIGS. 1 through 3, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

FIG. 1 illustrates a first example system 100 for identifying at least one faulty light emitting diode (LED) in multiple strings of LEDs according to this disclosure. As shown in FIG. 1, the system 100 includes or is coupled to multiple LEDs 102. Each LED 102 represents any suitable semiconductor structure for generating visible light or other illumination. The LEDs 102 are coupled in series to form multiple strings 104a-104b. In this example, there are ten LEDs 102 in each string 104a-104b, although any number of LEDs 102 could be used in the strings 104a-104b (such as eight or twelve LEDs in each string). Also, while two strings 104a-104b are shown here, any number of strings could be used, such as three or more strings coupled in parallel.

An LED driver 106 drives the LEDs 102 and causes the LEDs 102 to generate illumination. For example, the LED driver 106 could repeatedly turn the LEDs 102 on and off at a specified duty cycle to generate a specified amount of illumination. The LED driver 106 could also control the peak current through the LEDs 102, the average current through the LEDs 102, or some other aspect of the LEDs 102. The LED driver 106 includes any suitable structure for driving LEDs.

An output capacitor 108 is coupled in parallel with the strings 104a-104b of LEDs 102. The output capacitor 108 represents any suitable capacitive structure having any suitable capacitance. In this example, a voltage across the output capacitor 108 is denoted V_{LED} and represents the string voltage of the LEDs 102.

A forward voltage V_{F} across each LED 102 in each string 104a-104b could vary widely during normal operation, such as between 2.6V and 4.0V. This variation could be caused by any number of factors, such as temperature variations, driving current changes, or design differences. Because the voltage across each LED string 104a-104b varies naturally, it is often difficult to detect variations caused by a short circuit or other fault in one or several of the LEDs 102.

In accordance with this disclosure, the system 100 implements a technique for detecting when one or more LEDs 102 in the strings 104a-104b experience a short circuit condition or other fault. In this embodiment, a control unit 110 receives a voltage associated with a node in each of the LED strings 104a-104b. In this case, the control unit 110 receives a voltage from a bottom node of each string 104a-104b. However, the control unit 110 could also receive voltages from any other node(s) of the strings 104a-104b, such as intermediate nodes. An “intermediate node” denotes a node in an LED string that follows a first LED's output in the string and that precedes a last LED's input in the string.

The control unit 110 uses the voltages from the strings 104a-104b to determine if a fault has occurred with one or more of the LEDs 102 in the strings 104a-104b. For example, the control unit 110 could determine whether a voltage difference V_{DIFF} between the voltage from the string 104a and the voltage from the string 104b exceeds a threshold. The voltage difference V_{DIFF} may be relatively small (even approaching zero) when all LEDs 102 in the strings 104a-104b are operating properly. However, the voltage difference V_{DIFF} can increase dramatically if at least one LED 102 in one string 104a-104b short circuits.

As a particular example, the voltage difference V_{DIFF} might not exceed several hundred millivolts (such as about 200 mV) when all LEDs 102 are operating properly, even over a wide range of temperatures (such as about 0° C. to about 90° C.) and driving currents (such as about 50 mA to about 350 mA). However, if one of the LEDs 102 in one string 104a-104b shorts, the voltage difference V_{DIFF} could increase substantially, such as up to about V_{F} (which could be around 3.2V in specific cases).

By comparing the voltage difference V_{DIFF} to a threshold, the control unit 110 can detect if and when one or more of the LEDs 102 in the strings 104a-104b short circuit. The control unit 110 could then take any suitable corrective action. For example, the control unit 110 could output a signal indicating that a fault has been detected. The signal could be provided to any suitable destination, such as the LED driver 106 or an external controller or other device or system. In this way, the voltage difference V_{DIFF} can be used to identify a fault in one or more LEDs 102 over a wide range of temperatures, driving currents, or other variations.

The control unit 110 includes any suitable structure for identifying a fault in one or more LEDs. For instance, the control unit 110 could include at least one comparator for comparing the voltage difference V_{DIFF} to a threshold value.

In this example, it is assumed that the voltage drop across each LED string 104a-104b is generally equal. This could be accomplished by using the same number of LEDs 102 in each LED string 104a-104b, where the LEDs 102 have substantially common operating characteristics (such as common forward voltage variations over temperature and drive current). This could be done by using LEDs having a common brightness index number (BIN).

The system 100 shown in FIG. 1 could form part of any larger device or system. For example, the LEDs 102 could form part or all of a vehicle headlamp. The LEDs 102 could also form part or all of a display in a mobile telephone, a laptop computer, a desktop computer monitor, or other display device.

Although FIG. 1 illustrates a first example of a system 100 for identifying at least one faulty LED 102 in multiple strings 104a-104b of LEDs, various changes may be made to FIG. 1. For example, the system 100 could include any number of LEDs 102, LED strings 104a-104b, LED drivers 106, capacitors 108, and control units 110. Also, various components in FIG. 1 could be combined, further subdivided, rearranged, or omitted and additional components could be added according to particular needs. For instance, the control unit 110 could be incorporated into the LED driver 106.

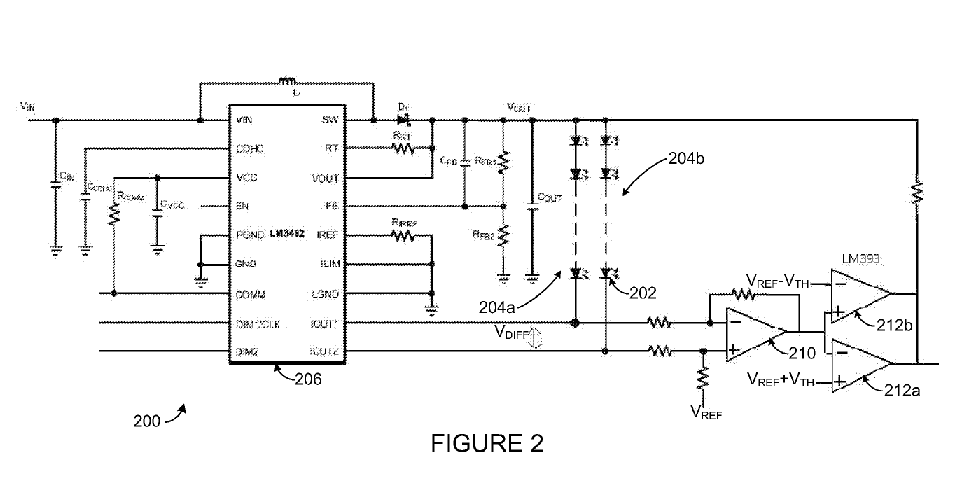

FIG. 2 illustrates a second example system 200 for identifying at least one faulty LED in multiple strings of LEDs according to this disclosure. In particular, FIG. 2 illustrates a more specific implementation of the LED fault detection mechanism described above with respect to FIG. 1.

As shown in FIG. 2, the system 200 includes multiple LEDs 202 that are coupled in series to form multiple strings 204a-204b. An LED driver 206 is used to drive the LEDs 202 in order to generate illumination. In this example, the LED driver 206 represents an LM3492 two-channel LED driver from NATIONAL SEMICONDUCTOR CORPORATION. However, any other suitable LED driver 206 could be used in the system 200.

Voltages from the LED strings 204a-204b are provided to a control circuit that includes a differential amplifier 210 and comparators 212a-212b. The comparators 212a-212b in this example are implemented using a single LM393 dual comparator from NATIONAL SEMICONDUCTOR CORPORATION, although any other suitable comparators could be used. The differential amplifier 210 receives the voltages from the strings 204a-204b and amplifies the voltage difference V_{DIFF} between the input voltages. In the system 200, the differential amplifier 210 receives a reference voltage V_{REF} as a bias voltage, so ideally the differential amplifier 210 outputs a voltage of about V_{REF} when V_{DIFF} equals zero. The comparators 212a-212b form a windowed comparator that determines if the output of the differential amplifier 210 is within a threshold amount of the reference voltage V_{REF}. The threshold amount is defined by a threshold voltage ±V_{TH}, which could represent about ±2.5V for detecting one failed LED. In this case, the comparator 212a determines if and when the output of the amplifier 210 exceeds a voltage limit V_{REF}+V_{TH}, and the comparator 212b determines if and when the output of the amplifier 210 falls below a voltage limit V_{REF}−V_{TH}. The output signals from the comparators 212a-212b could be provided to any suitable external destination(s), such as a microprocessor or microcontroller, which can use the signals from the comparators 212a-212b to trigger an alarm or take other corrective action.

The remaining components in FIG. 2 are used in conjunction with the LED driver 206 to achieve desired functionality. The remaining components include diodes, resistors, capacitors, and inductors. These components are related to setting up and operating the specific LED driver 206 shown here and are not discussed further since a person skilled in the art would understand the use of these components with the specified LED driver 206.

In this way, the system 200 once again is able to detect when a voltage difference between voltages in multiple LED strings deviates from an expected voltage. This deviation can be indicative of a shorted LED 202 or other problem, and the system 200 can take suitable corrective action.

Although FIG. 2 illustrates a second example of a system 200 for identifying at least one faulty LED 202 in multiple strings 204a-204b of LEDs, various changes may be made to FIG. 2. For example, the system 200 could include any number of each component. Also, various components in FIG. 2 could be combined, further subdivided, rearranged, or omitted and additional components could be added according to particular needs. Moreover, it is assumed that the LEDs 202 have substantially common operating characteristics and that the same number of LEDs 202 are used in each string. Further, while specific components and component values (such as specific parts and voltages) are shown in FIG. 2 or described above, these components and component values are for illustration only. Any other or additional circuit components could be used to provide the desired functionality in the system 200. In addition, features shown in FIG. 1 could be used in FIG. 2 or vice versa. For instance, the control unit 110 could use the amplifier 210 and comparators 212a-212b to detect LED faults.

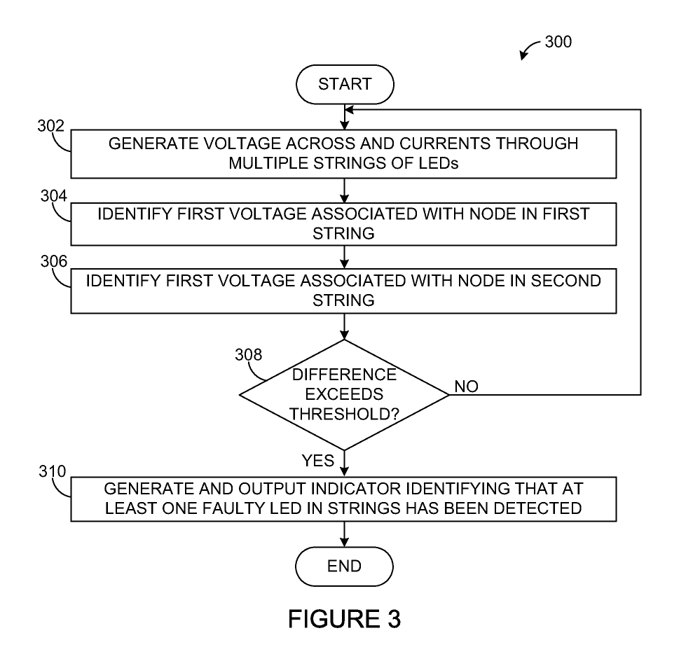

FIG. 3 illustrates an example method 300 for identifying at least one faulty LED in multiple strings of LEDs according to this disclosure. The method 300 could be used with any suitable system, including the system 100 of FIG. 1, the system 200 of FIG. 2, or other system.

As shown in FIG. 3, a voltage is generated across and currents are generated through multiple strings of LEDs at step 302. This could include, for example, the LED driver 106 or 206 generating a string voltage V_{LED} and currents through the LEDs 102 or 202. The string voltage V_{LED} and the currents could be generated in order to provide a desired level of illumination from the strings 104a-104b or 204a-204b.

A first voltage associated with a node in a first string is identified at step 304, and a second voltage associated with a node in a second string is identified at step 306. This could include, for example, receiving a first voltage from a node in the string 104a or 204a, such as from a bottom node in the string 104a or 204a. This could also include receiving a second voltage from a node in the string 104b or 204b, such as from a bottom node in the string 104b or 204b.

A determination is made whether a difference between the first and second voltages exceeds a threshold at step 308. This could include, for example, the control unit 110 determining a difference between the first and second voltages and comparing the difference to a threshold. This could also include the amplifier 210 amplifying the difference between the first and second voltages and the comparators 212a-212b determining whether the output of the amplifier 210 falls within a voltage range defined by a threshold V_{REF}±V_{TH}. Any other suitable technique could be used to identify whether a difference between first and second voltages exceeds a threshold.

If no threshold violation occurs, the method 300 returns to step 302, and the system may continue to generate illumination using the LED strings. If a threshold violation occurs, this is indicative of an LED short or other fault in at least one of the LED strings. In that case, corrective action can be taken, such as generating and outputting an indicator identifying that one or more faulty LEDs have been detected in the strings at step 310. Any other or additional corrective action could be taken, such as shutting off the LEDs 102 or 202 or adjusting the voltage across or current through the LEDs.

Although FIG. 3 illustrates one example of a method 300 for identifying at least one faulty LED in multiple strings of LEDs, various changes may be made to FIG. 3. For example, while shown as a series of steps, various steps in FIG. 3 could overlap, occur in parallel, occur in a different order, or occur any number of times.

It may be advantageous to set forth definitions of certain words and phrases that have been used within this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with”, as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like.

While this disclosure has described certain embodiments and generally associated methods, alterations and permutations of these embodiments and methods will be apparent to those skilled in the art. Accordingly, the above description of example embodiments does not define or constrain this invention. Other changes, substitutions, and alterations are also possible without departing from the spirit and scope of this invention as defined by the following claims.

What is claimed is:

1. An apparatus comprising:
a control unit configured to receive (i) a first voltage from a first node associated with a first string of multiple light emitting diodes (LEDs) and (ii) a second voltage from a second node associated with a second string of multiple LEDs;
the control unit also configured to identify whether at least one of the LEDs has a fault using the first and second voltages.

2. The apparatus of claim 1, wherein the control unit is configured to compare a difference between the first and second voltages to a threshold.

3. The apparatus of claim 1, wherein:
the control unit is further configured to receive a higher voltage limit and a lower voltage limit defining a voltage range; and
the control unit is configured to determine whether a difference between the first and second voltages falls within the voltage range.

4. The apparatus of claim 3, wherein the control unit comprises:
a differential amplifier configured to receive the first and second voltages, the differential amplifier also configured to receive a reference voltage as a bias voltage.

5. The apparatus of claim 4, wherein the control unit further comprises:
a first comparator configured to compare an output of the differential amplifier to the higher voltage limit; and
a second comparator configured to compare the output of the differential amplifier to the lower voltage limit.

6. The apparatus of claim 5, wherein:
the differential amplifier is configured to output the reference voltage when the first and second voltages are equal;
the first comparator is configured to compare the output of the differential amplifier to a sum of the reference voltage and about +2.5V; and
the second comparator is configured to compare the output of the differential amplifier to a sum of the reference voltage and about −2.5V.

7. The apparatus of claim 1, wherein the control unit is configured to be coupled to the strings of LEDs in a vehicle headlamp.

8. The apparatus of claim 1, wherein the control unit is configured to be coupled to the strings of LEDs in a display of an electronic device.

9. A system comprising:
first and second strings each comprising multiple light emitting diodes (LEDs); and
a control unit configured to receive (i) a first voltage from a first node associated with the first string of LEDs and (ii) a second voltage from a second node associated with the second string of LEDs;
the control unit also configured to identify whether at least one of the LEDs has a fault using the first and second voltages.

10. The system of claim 9, wherein:
the control unit is coupled to a bottom node of the first string of LEDs; and
the control unit is coupled to a bottom node of the second string of LEDs.

11. The system of claim 9, wherein the control unit is configured to compare a difference between the first and second voltages to a threshold.

12. The system of claim 9, wherein:
the control unit is further configured to receive a higher voltage limit and a lower voltage limit defining a voltage range; and
the control unit is configured to determine whether a difference between the first and second voltages falls within the voltage range.

13. The system of claim 12, wherein the control unit comprises:
a differential amplifier configured to receive the first and second voltages, the differential amplifier also configured to receive a reference voltage as a bias voltage.

14. The system of claim 13, wherein the control unit further comprises:
a first comparator configured to compare an output of the differential amplifier to the higher voltage limit; and
a second comparator configured to compare the output of the differential amplifier to the lower voltage limit.

15. The system of claim 9, wherein the strings of LEDs comprise strings of LEDs in a vehicle headlamp.

16. The system of claim 9, wherein the strings of LEDs comprise strings of LEDs in a display of an electronic device.

17. A method comprising:
receiving a first voltage from a first node associated with a first string of multiple light emitting diodes (LEDs);
receiving a second voltage from a second node associated with a second string of multiple LEDs; and
identifying whether at least one of the LEDs has a fault using the first and second voltages.

18. The method of claim 17, wherein identifying whether at least one of the LEDs has a fault comprises comparing a difference between the first and second voltages to a threshold.

19. The method of claim 17, wherein identifying whether at least one of the LEDs has a fault comprises determining whether a difference between the first and second voltages falls within a voltage range defined by higher and lower voltage limits.

20. The method of claim 17, wherein the strings of LEDs comprises strings of LEDs in a vehicle headlamp.
